(19) United States
(12) Patent Application Publication
(10) Pub. No.: US 2022/0006046 A1
(43) Pub. Date: Jan. 6, 2022

(54) DISPLAY PANEL AND METHOD FOR PACKAGING THE SAME, AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Xiaodong YANG, Beijing (CN); Duanming LI, Beijing (CN); Quanqin SUN, Beijing (CN); Qin ZHANG, Beijing (CN); Shuai ZHANG, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 16/338,466

(22) PCT Filed: Sep. 5, 2018
(86) PCT No.: PCT/CN2018/104121

§ 371 Date: Mar. 30, 2019

(30) Foreign Application Priority Data
Nov. 30, 2017 (CN) 201711240035.2

(51) Int. Cl. H01L 51/52; H01L 51/56

(52) U.S. Cl. CPC H01L 51/5253; H01L 51/56

(57) ABSTRACT

The present disclosure provides a display panel, a method for packaging the same, and a display device. The display panel comprises a display substrate and at least one package film layer covering the display substrate, wherein the package film layer comprises a first inorganic film, a second inorganic film, an organic film and a third inorganic film laminated on the display substrate in sequence, wherein an adhesion between a material of the first inorganic film and a material of the organic film is less than an adhesion between a material of the second inorganic film and a material of the organic film.

### CROSS-REFERENCE TO RELATED APPLICATION

This application claims a priority to Chinese Patent Application No. 201711240035.2 filed on Nov. 30, 2017, the disclosures of which are incorporated in their entirety by reference herein.

### TECHNICAL FIELD

The present disclosure relates to the field of display technology, in particular to a display panel and a method for packaging the same, and a display device comprising the display panel.

### BACKGROUND

The development trends of Organic Light-Emitting Diode (OLED) display screens are narrow bezel, low power consumption, bendability, foldability and the like. The package film layer of the existing flexible OLED package structure comprises an organic film and an inorganic film laminated in sequence. In manufacturing the organic film, the organic film is formed by inkjet printing a rheological organic material, such as an acrylic material, in a filled region surrounded by a barrier and then making the rheological organic material solidify in the filled region.

### SUMMARY

In an aspect, a display panel is provided, comprising a display substrate and at least one package film layer covering the display substrate, wherein the package film layer comprises a first inorganic film, a second inorganic film, an organic film and a third inorganic film laminated on the display substrate in sequence, and wherein an adhesion between a material of the first inorganic film and a material of the organic film is less than an adhesion between a material of the second inorganic film and a material of the organic film.

Alternatively, the display panel comprises a display region and a non-display region, the non-display region comprising a first region provided with a barrier structure and a second region between the display region and the barrier structure, the first inorganic film covering the second region and the barrier structure, and the second inorganic film and the organic film cover the second region but not cover the barrier structure.

Alternatively, the third inorganic film covers the second region and the barrier structure.

Alternatively, the third inorganic film and the first inorganic film are made of a same material.

Alternatively, the at least one package film layer comprises two package film layers.

Alternatively, the two package film layers comprises a first package film layer and a second package film layer laminated in sequence, the third inorganic film of the first package film layer is reused as the first inorganic film of the second package film layer.

Alternatively, the first inorganic film is made of silicon nitride, the second inorganic film is made of silicon oxynitride, and the third inorganic film is made of silicon nitride.

Alternatively, the first inorganic film has a thickness of 500 nm to 1000 nm, the second inorganic film has a thickness of 50 nm to 100 nm, and the third inorganic film has a thickness of 500 nm to 1000 nm.

Alternatively, the barrier structure comprises at least a first barrier and a second barrier, a distance between the first barrier and the display region is less than a distance between the second barrier and the display region, and a height of the first barrier is less than a height of the second barrier.

Alternatively, the display substrate is an Organic Light-Emitting Diode (OLED) display substrate.

An embodiment of the present disclosure further provides a display device including the display panel as described above.

An embodiment of the present disclosure further provides a method for packaging a display panel, comprising forming at least one package film layer on a display substrate for covering the display substrate, wherein a step of forming the package film layer comprises:

laminating a first inorganic film, a second inorganic film, an organic film and a third inorganic film on the display substrate in sequence, wherein an adhesion between a material of the first inorganic film and a material of the organic film is less than an adhesion between a material of the second inorganic film and a material of the organic film.

Alternatively, the display panel comprises a display region and a non-display region, the non-display region comprising a first region provided with a barrier structure and a second region between the display region and the barrier structure, the method for packaging comprises:

forming the first inorganic film covering the second region and the barrier structure;

forming the second inorganic film covering the second region but not covering the barrier structure; and

covering the second inorganic film with a rheological organic material, wherein the rheological organic material is blocked on a surface of the second inorganic film by the barrier structure and leveled to form the organic film, and the organic film covers the second region but not covers the barrier structure.

### BRIEF DESCRIPTION OF THE DRAWINGS

FIG. 1 is a schematic diagram of a related OLED display panel.

FIG. 2 is a schematic diagram of a display panel according to an embodiment of the present disclosure.

FIG. 3 is a schematic diagram of a display panel according to another embodiment of the present disclosure.

### DETAILED DESCRIPTION

In order to make the technical problems to be solved, the technical solutions, and the advantages of the embodiments of the present disclosure, the present disclosure will be described hereinafter in conjunction with the drawings and specific examples.

The development trends of OLED display screens are narrow bezel, low power consumption, bendability, foldability and the like. The packaging process of the related flexible OLED package structure mainly comprises: manufacturing a flexible substrate; manufacturing a first gate insulating layer; manufacturing a first gate metal layer pattern; manufacturing a second gate insulating layer; manufacturing a second gate metal layer pattern; manufacturing an interlayer insulating layer; manufacturing the source-drain metal layer pattern; manufacturing an overcoat; manufacturing an anode; manufacturing a pixel defining layer; manufacturing a spacer layer manufacturing a cathode; manufacturing a package film layer. The package film layer comprises an organic film and an inorganic film laminated in sequence. In manufacturing the organic film, an organic film is formed by inkjet printing a rheological organic material, such as an acrylic material, in a filled region surrounded by a barrier and making the rheological organic material in the filled region solidifying.

In order to ensure the display quality of the OLED display screen, the package film layer needs to concern both the high water-oxygen barrier capacity and the uniformity of the organic film. However, the related package film layer cannot concern both the high water-oxygen barrier capacity and the uniformity of the organic film.

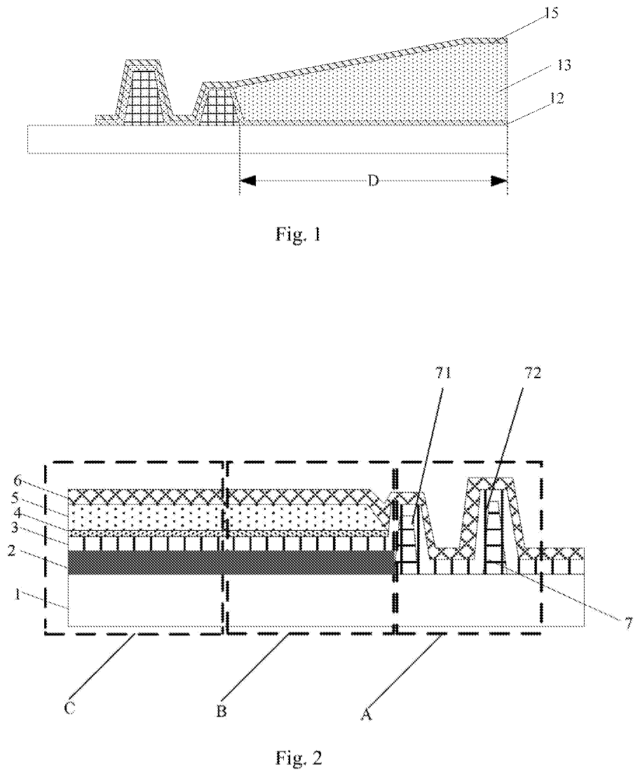

The package film layer may be a laminated structure of an inorganic film/an organic film/an inorganic film. The inorganic film may be made by various common film forming methods. Alternatively, the film is formed by CVD (Chemical Vapor Deposition) process, and the inorganic film (silicon nitride layer or silicon oxynitride layer) formed by CVD process has strong water-oxygen barrier capacity, good light transmittance and good wear resistance. Among silicon nitride (for example, SiNx) and silicon oxynitride (for example, SiON), silicon nitride has a better water-oxygen barrier capacity, but has a relatively poor adhesion to the material of the organic film; while silicon oxynitride has a relatively poor water-oxygen barrier capacity, but has a better adhesion to the material of the organic film and allows the organic ink to have a better fluidity. If a silicon nitride layer/organic film/silicon nitride layer is used as the package film layer, the uniformity of the organic film will be relatively poor, because the rheological organic material has a relatively poor leveling diffusion property on the surface of silicon nitride layer. As shown in FIG. 1, if the silicon oxynitride layer 12/organic film 13/silicon nitride layer 15 is used as the package film layer, the water-oxygen barrier capacity of the entire package film layer is relatively poor, because the silicon oxynitride layer 12 has a relatively poor water-oxygen barrier capacity; and, the climbing distance D of the organic film 13 is relatively large, which is not conducive to achieving a narrow bezel of the display device, because the rheological organic material has a relatively good leveling diffusion property on the surface of silicon nitride layer. To sum up, the above-mentioned package film layer cannot concern both the high water-oxygen barrier capacity and the uniformity of the organic film.

In order to solve the above technical problems, embodiments of the present disclosure provide a display panel and a display device comprising the display panel, which are capable of concerning both the high water-oxygen barrier capacity and the uniformity of the organic film.

An embodiment of the present disclosure provides a display panel, as shown in FIG. 2, comprising a display substrate and at least one package film layer covering the display substrate, the package film layer comprising a first inorganic film 3, a second inorganic film 4, an organic film 5 and a third inorganic film 6 laminated on the display substrate in sequence, wherein an adhesion between a material of the first inorganic film 3 to a material of the organic film 5 is less than an adhesion between a material of the second inorganic film 4 to a material of the organic film 5.

In the present embodiment, since the adhesion between the material of the first inorganic film and the material of the organic film is less than the adhesion between the material of the second inorganic film and the material of the organic film, when the rheological organic material is formed on the second inorganic film, the rheological organic material has a relatively good leveling diffusion property on the surface of the second inorganic film, thereby being capable of forming an organic film having relatively good uniformity. Moreover, since the adhesion between the material of the first inorganic film and the material of the organic film is relatively weak, it is ensured that the package film layer has a relatively good water-oxygen barrier capacity.

Alternatively, as shown in FIG. 2, the display panel comprises a display region C and a non-display region, the non-display region including a first region A provided for a barrier structure and a second region B between the display region and the barrier structure. In the second region B, a device layer 2 on the base substrate 1 is provided. The device layer 2 may, for example, comprises an anode layer and a cathode layer. In the non-display region, the first inorganic film 3 covers the second region B and the barrier structure, and the second inorganic film 4 and the organic film 5 only cover the second region B but not cover the barrier structure. Since the first inorganic film 3 covers the second region B and the barrier structure, and the second inorganic film 4 and the organic film 5 cover the second region B but not covers the barrier structure, when the rheological organic material is leveled on the surface of the second inorganic film 4 and diffuses to the barrier structure, it is possible to prevent the rheological organic material from diffusing to the barrier structure, and confines the organic film 5 to the range defined by the barrier structure. This is because the adhesion between the material of the first inorganic film 3 covering the barrier structure and the material of the organic film 5 is relatively weak. Therefore, the rheological organic material, before passing over the barrier structure, solidifies to form the organic film 5, which contributes to realizing a narrow bezel of the display device.

In some embodiments, the constituent materials of the third inorganic film 6 and the first inorganic film 3 may be the same. That is, an adhesion between a material of the third inorganic film 6 to a material of the organic film 5 is less than an adhesion between a material of the second inorganic film 4 to a material of the organic film 5, or relatively weak.

Alternatively, as shown in FIG. 2, the third inorganic film 6 covers the second region B and the barrier structure. Since the adhesion between the material of the third inorganic film 6 to the material of the organic film 5 is relatively weak, and the inorganic film has a stronger water-oxygen barrier capacity compared with the organic film, the third inorganic film 6 covers the second region B and the barrier structure, which contributes to ensuring the water-oxygen barrier capacity of the package film layer.

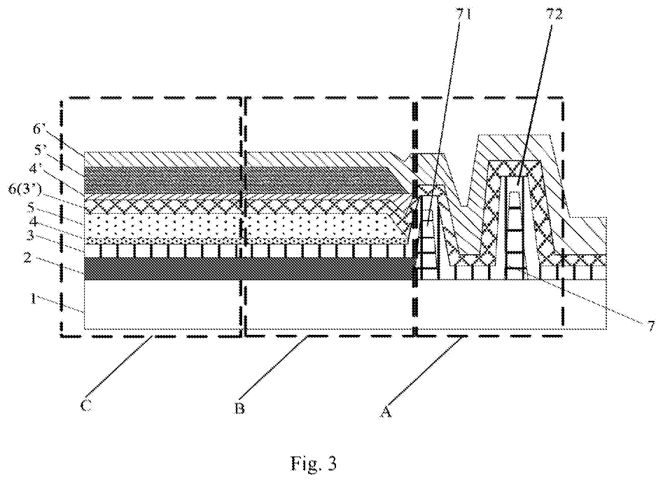

Alternatively, when the at least one package film layer comprises a first package film layer and a second package film layer laminated in sequence, the third inorganic film 6 of the first package film layer is reused as the first inorganic film 3 of the second package film layer. As shown in FIG. 3, the first package film layer comprises a first inorganic film 3, a second inorganic film 4, an organic film 5, and a third inorganic film 6; and the second package film layer comprises a first inorganic film 3′, and a second inorganic film 4′, an organic film 5′, and an third inorganic film 6, wherein the third inorganic film 6 of the first package film is reused as the first inorganic film 3′ of the second package film layer, that is, the third inorganic film 6 is the same as the first inorganic film 3′. The package structure can minimize the thickness of the package film layer.

Alternatively, the first inorganic film 3 has a thickness of 500 nm to 1000 nm, the second inorganic film 4 has a thickness of 50 nm to 100 nm, and the third inorganic film 6 has a thickness of 500 nm to 1000 nm.

In an alternative embodiment, the first inorganic film 3 is made of silicon nitride, the second inorganic film 4 is made of silicon oxynitride, and the third inorganic film 6 is made of silicon nitride, that is, the package film layer has a structure of a silicon nitride film/a silicon oxynitride film/an organic film 5/a silicon nitride film. The two layers of silicon nitride film are manufactured by process parameters with a high water resistance, and have a thickness of about 500 nm to 1000 nm; and the silicon oxynitride film is manufactured by process parameters with a good diffusion capacity, and has a thickness of about 50 nm to 100 nm. When the above parameters are used, the thickness of the package film layer can be relatively small, and the package film layer can have a relatively good water-oxygen barrier capacity.

In the package film layer, the adhesion between the silicon nitride film and the organic film 5 is relatively poor, and the adhesion between the silicon oxynitride film and the organic film 5 is relatively good. As shown in FIG. 2, the edge of the silicon oxynitride film is closely contact with the inside of the barrier 7 proximate to the display region, and the edge of the two silicon nitride films are designed to be outside of the barrier 7 in the outermost side. When the rheological organic material flows to the inside of the barrier 7 proximate to the display region, the rheological organic material will maintain good diffusibility and uniformity due to the effect of the silicon oxynitride film. When the rheological organic material is close to the barrier 7 proximate to the display region, due to the effect of the silicon nitride film, the climbing distance of the organic film 5 can be reduced, and finally the overall water-oxygen barrier capacity of the package film layer can be improved and the climb distance of the organic film can be reduced.

Alternatively, as shown in FIG. 2, the barrier structure comprises at least a first barrier 71 and a second barrier 72 separated by a predetermined distance, the distance between the first barrier 71 and the display region is less than a distance between the second barrier 72 and the display region, and a height of the first barrier 71 is less than a height of the second barrier 72. The first barrier 71 and the second barrier 72 are capable of forming a stepped structure, which better presents the rheological organic material from crossing the barrier structure.

Alternatively, the display substrate is an OLED display substrate. The technical solution of the embodiment allows the OLED display panel to have a relatively good water-oxygen barrier capacity, and a relatively good uniformity of the organic film.

An embodiment of the present disclosure further provides a display device comprising the display panel as described above. The display device may be any product or component having a display function, such as a television, a display, a digital photo frame, a mobile phone, a tablet computer, etc. The display device further comprises a flexible circuit board, a printed circuit board, and a backplane.

The display device of the embodiment has a relatively good water-oxygen barrier capacity and a relatively good uniformity of the organic film, thereby ensuring the service life of the display device. In addition, the climbing distance of the organic film 5 is relatively short, so that the design distance between the edge of the display region and the barrier structure can be reduced, that is, the width of the second region B can be designed to be narrower, which contributes to a narrow bezel of the display device.

An embodiment of the present disclosure further provides a method for packaging a display panel, comprising forming at least one package film layer on a display substrate for covering the display substrate, wherein the step of forming the package film layer comprises:

laminating a first inorganic film 3, a second inorganic film 4, an organic film 5 and a first inorganic film 3 on the display substrate in sequence, wherein an adhesion between a material of the first inorganic film 3 to a material of the organic film 5 is less than an adhesion between a material of the second inorganic film 4 to a material of the organic film 5.

In the present embodiment, since the adhesion between the material of the first inorganic film and the material of the organic film is less than the adhesion between the material of the second inorganic film and the material of the organic film, when the rheological organic material is formed on the second inorganic film, it is capable of forming an organic film having relatively good uniformity. This is because the rheological diffusion property of the rheological organic material on the surface of the second inorganic film is relatively good. Moreover, since the adhesion between the material of the first inorganic film and the material of the organic film is relatively weak, it is ensured that the package film layer has a relatively good water-oxygen barrier capacity.

Alternatively, the display panel comprises a display region and a non-display region, as shown in FIG. 2, the non-display region comprising a first region A provided with a barrier structure and a second region B between the display region and the first region A. The method for packaging comprises:

forming a first inorganic film 3 covering the second region B and the barrier structure;

forming a second inorganic film 4 covering the second region B but not covering the barrier structure; and

covering the second inorganic film 4 with a rheological organic material, wherein the rheological organic material is blocked on a surface of the second inorganic film 4 by the barrier structure and leveled to form the organic film 5, and the organic film 5 only covers the second region B but not covers the barrier structure.

Alternatively, the rheological organic material may be printed on the second inorganic film 4.

When the rheological organic material is leveled on the surface of the second inorganic film 4 and diffuses to the barrier structure, since the adhesion between the material of the first inorganic film 3 covering the barrier structure and the material of the organic film 5 is relatively weak, it is possible to prevent the rheological organic material from diffusing to the barrier structure, thereby confining the organic film 5 to the range defined by the barrier structure. This contribute to solidifying the rheological organic material, before passing over the barrier structure, to form the organic film 5, which contributes to realizing a narrow bezel of the display device.

When the display substrate of the embodiment is an OLED display substrate, the method for packaging the display panel of the embodiment specifically comprises the following steps:

1. After the OLED display substrate is manufactured, a silicon nitride film covering a display region of an OLED display substrate, a second region B and a barrier structure and having a thickness of about 500 nm to 1000 nm is manufactured by CVD process, wherein the edge of the silicon nitride film is located outside of the barrier 7 proximate to the edge of the substrate;

2. A silicon oxynitride film having a thickness of about 50 nm to 100 nm is manufactured by CVD process, wherein the silicon oxynitride film covers a display region of the OLED display substrate and the second region B but not cover the barrier structure, and the edge of the silicon oxynitride film is in closely contact with the inside of the barrier 7 proximate to the display region;

3. An organic film 5 is manufactured by an ink-jet printing (UP) process, wherein the organic film 5 covers the display region of the OLED display substrate and the second region B but not cover the barrier structure, and the edge of the organic film 5 is in closely contact with the inside of the barrier 7 proximate to the display region; and

4. A silicon nitride film covering a display region of an OLED display substrate, a second region B and a barrier structure and having a thickness of about 500 nm to 1000 nm is manufactured by CVD process, wherein the edge of the silicon nitride film is located outside of the barrier 7 proximate to the edge of the substrate.

The package structure can be manufactured through the above steps 1 to 4. In the embodiment, each of the package film layers comprises a silicon nitride film, a silicon oxynitride film, an organic film, and a silicon nitride film laminated in sequence. Since the adhesion between the silicon nitride film and the organic film is relatively weak and the adhesion between the silicon oxynitride film and the organic film is relatively good, when the rheological organic material is printed on the silicon oxynitride film, the rheological organic material has a relatively good leveling diffusion property on the surface of the silicon oxynitride film, thereby forming an organic film with a relatively good uniformity. Since the adhesion between the silicon nitride film and the organic film is relatively weak and the silicon nitride film has a relatively good water-oxygen barrier capacity, the package film layer can ensure a relatively good water-oxygen barrier capacity.

Unless otherwise defined, technical terms or scientific terms used herein have the normal meaning commonly understood by one skilled in the art in the field of the present disclosure. The words “first”, “second”, and the like used in the present disclosure does not denote any order, quantity, or importance, but rather merely serves to distinguish different components. The “including”, “comprising”, and the like used in the present disclosure means that the element or item appeared in front of the word encompasses the element or item and their equivalents listed after the word, and does exclude other elements or items. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

It will be understood that when an element, such as a layer, film, region, or substrate, is referred to as being “on” or “under” another element, the element may be directly “on” or “under” another element, or there may be an intermediate element.

The above descriptions are alternative embodiments of the present disclosure. It should be noted that one skilled in the art would make some improvements and substitutions without departing from the principles of the present disclosure. These improvements and modifications should also be regarded as the protection scope of the present disclosure.

1. A display panel comprising a display substrate and at least one package film layer covering the display substrate, wherein the package film layer comprises a first inorganic film, a second inorganic film, an organic film and a third inorganic film laminated on the display substrate in sequence, and an adhesion between a material of the first inorganic film and a material of the organic film is less than an adhesion between a material of the second inorganic film and a material of the organic film.

2. The display panel of claim 1, wherein the display panel comprises a display region and a non-display region, the non-display region comprises a first region provided with a barrier structure and a second region between the display region and the barrier structure, the first inorganic film covers the second region and the barrier structure, and the second inorganic film and the organic film cover the second region but not cover the barrier structure.

3. The display panel of claim 2, wherein the third inorganic film covers the second region and the barrier structure.

4. The display panel of claim 1, wherein the third inorganic film and the first inorganic film are made of a same material.

5. The display panel of claim 1, wherein the at least one package film layer comprises two package film layers.

6. The display panel of claim 5, wherein the two package film layers comprise a first package film layer and a second package film layer, the third inorganic film of the first package film layer is reused as the first inorganic film of the second package film layer.

7. The display panel of claim 1, wherein the first inorganic film is made of silicon nitride, the second inorganic film is made of silicon oxynitride, and the third inorganic film is made of silicon nitride.

8. The display panel of claim 7, wherein the first inorganic film has a thickness of 500 nm to 1000 nm, the second inorganic film has a thickness of 50 nm to 100 nm, and the third inorganic film has a thickness of 500 nm to 1000 nm.

9. The display panel of claim 2, wherein the barrier structure comprises at least a first barrier and a second barrier, a distance between the first barrier and the display region is less than a distance between the second barrier and the display region, and a height of the first barrier is less than a height of the second barrier.

10. The display panel of claim 1, wherein the display substrate is an Organic Light-Emitting Diode (OLED) display substrate.

11. A display device, comprising the display panel of claim 1.

12. A method for packaging a display panel, comprising forming at least one package film layer on a display substrate for covering the display substrate, wherein the step of forming the package film layer comprises:
laminating a first inorganic film, a second inorganic film, an organic film and a third inorganic film on the display substrate in sequence, wherein an adhesion between a material of the first inorganic film and a material of the organic film is less than an adhesion between a material of the second inorganic film and a material of the organic film.

13. The method of claim 12, wherein the display panel comprises a display region and a non-display region, and the non-display region comprises a first region provided with a barrier structure and a second region between the display region and the barrier structure, and wherein the method for packaging comprises:
forming the first inorganic film covering the second region and the barrier structure;
forming the second inorganic film covering the second region but not covering the barrier structure; and
covering the second inorganic film with a rheological organic material, wherein the rheological organic material is blocked on a surface of the second inorganic film by the barrier structure and leveled to form the organic film, and the organic film covers the second region but not covers the barrier structure.

14. The display device of claim 11, wherein the display panel comprises a display region and a non-display region, the non-display region comprises a first region provided with a barrier structure and a second region between the display region and the barrier structure, the first inorganic film covers the second region and the barrier structure, and the second inorganic film and the organic film cover the second region but not cover the barrier structure.

15. The display device of claim 14, wherein the third inorganic film covers the second region and the barrier structure.

16. The display device of claim 11, wherein the third inorganic film and the first inorganic film are made of a same material.

17. The display device of claim 11, wherein the at least one package film layer comprises two package film layers.

18. The display device of claim 17, wherein the two package film layers comprise a first package film layer and a second package film layer, the third inorganic film of the first package film layer is reused as the first inorganic film of the second package film layer.

19. The display device of claim 11, wherein the first inorganic film is made of silicon nitride, the second inorganic film is made of silicon oxynitride, and the third inorganic film is made of silicon nitride, and wherein the first inorganic film has a thickness of 500 nm to 1000 nm, the second inorganic film has a thickness of 50 nm to 100 nm, and the third inorganic film has a thickness of 500 nm to 1000 nm.

20. The display device of claim 15, wherein the barrier structure comprises at least a first barrier and a second barrier, a distance between the first barrier and the display region is less than a distance between the second barrier and the display region, and a height of the first barrier is less than a height of the second barrier.
